(19) United States
(12) Patent Application Publication
(10) Pub. No.: US 2011/0079280 A1
(43) Pub. Date: Apr. 7, 2011

(54) SELF-REMEDIATING PHOTOVOLTAIC MODULE

(75) Inventors: Scott Christensen, Perrysburg, OH (US); Karina Krawczyk, Perrysburg, OH (US)

(73) Assignee: First Solar, Inc., Perrysburg, OH (US)

(21) Appl. No.: 12/895,805

(22) Filed: Sep. 30, 2010

Related U.S. Application Data
(60) Provisional application No. 61/247,910, filed on Oct. 1, 2009.

(51) Int. Cl. H01L 31/0216; H01L 31/18

(52) U.S. Cl. 136/256; 438/64; 257/E31.117

(57) ABSTRACT

A method for manufacturing a photovoltaic module may include forming a photovoltaic device including a constituent material; forming a hydrophilic material adjacent to the constituent material, where the hydrophilic material includes polyethylene; and depositing a remediation agent adjacent to the hydrophilic material, such that the remediation agent is proximate to, but not contacting the constituent material.

### CLAIM FOR PRIORITY

This application claims priority under 35 U.S.C. §119(e) to U.S. Provisional Patent Application Ser. No. 61/247,910 filed on Oct. 1, 2009, which is hereby incorporated by reference.

### TECHNICAL FIELD

The present invention relates to photovoltaic modules and methods of production.

### BACKGROUND

Photovoltaic modules can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic modules can also contain one or more transparent conductive oxide layers, which are also often conductors of electrical charge.

### DESCRIPTION OF DRAWINGS

FIG. 1 is a schematic of a photovoltaic module.

FIG. 2 is a schematic of a photovoltaic module with an encapsulation frame.

FIG. 3 is a schematic of a photovoltaic module.

FIG. 4 is a schematic of a photovoltaic module with an encapsulation frame.

FIG. 5 is a schematic of a photovoltaic module with an encapsulation frame.

FIG. 6 is a schematic of a photovoltaic module and cord plate.

### DETAILED DESCRIPTION

A method for manufacturing a photovoltaic module may include forming a photovoltaic device including a constituent material; forming a hydrophilic material adjacent to the constituent material, where the hydrophilic material includes polyethylene; and depositing a remediation agent adjacent to the hydrophilic material, such that the remediation agent is proximate to, but not contacting the constituent material.

The method may have various optional features. For example, the hydrophilic material may include a resin or a polymer. The polymer may include a glycol, an oxide, a methoxypolyethylene oxide, a dimethyl ether of polyethylene oxide, or any mixtures or combinations thereof. The constituent material may include a heavy metal, for example, cadmium. The constituent material may include a semiconductor absorber layer on a semiconductor window layer. The constituent material may include a cadmium telluride layer on a cadmium sulfide layer. The remediation agent may include a precipitating agent, a complexing agent, a sorbent, or a stabilization agent. The precipitating agent may include a sulfide, hydroxide, carbonate, phosphate, or silicate. For example, the precipitating agent may include a calcium carbonate, calcium hydroxide, calcium phosphate, or calcium sulfide. The complexing agent may include a nitrogen-containing group, a sulfur-containing group, a phosphorus-containing group, an acid, or a carbonyl group. For example, the complexing agent may include EDTA, cysteine, xanthates, or trimercaptotriazine. The complexing agent may include an ion exchange resin, beads, or membrane. The sorbent may include zeolites, metal oxides, zero valent iron, carbon, tannin-rich materials, modified natural fibers, and modified synthetic fibers. The sorbent may include an apatite, a clay, or an oxide. The stabilization agent may include a cementious material. The step of forming a hydrophilic material may include contacting the hydrophilic material to the constituent material. The step of forming a hydrophilic material may include encapsulating the remediation agent within the hydrophilic material. The step of forming a hydrophilic material may include depositing the hydrophilic material in the laser scribes of a heavy metal. The step of forming a hydrophilic material may include spin coating. The step of forming a hydrophilic material may include placing a free-standing film. The step of forming a hydrophilic material may include placing an extruded film. The hydrophilic material may be part of a base chain of a polymeric adhesive or interlayer material. The step of forming a hydrophilic material may include dispersing the hydrophilic material throughout an interlayer near a polymer-metal interface. The method may include laminating one or more layers, where the photovoltaic module includes the one or more layers.

A photovoltaic module may include a photovoltaic device including a constituent material; a remediation agent proximate to the constituent material, where the remediation agent is capable of remediating the constituent material; and a hydrophilic material positioned between the constituent material and the remediation agent, where the hydrophilic material includes polyethylene.

The photovoltaic module may have various optional features. For example, the hydrophilic material may include a resin or a polymer. The hydrophilic material may include a resin or a polymer. The polymer may include a glycol, an oxide, a methoxypolyethylene oxide, a dimethyl ether of polyethylene oxide, or any mixtures or combinations thereof. The constituent material may include a heavy metal, for example, cadmium. The constituent material may include a semiconductor absorber layer on a semiconductor window layer. The constituent material may include a cadmium telluride layer on a cadmium sulfide layer. The remediation agent may include a precipitating agent, a complexing agent, a sorbent, or a stabilization agent. The precipitating agent may include a sulfide, hydroxide, carbonate, phosphate, or silicate. For example, the precipitating agent may include a calcium carbonate, calcium hydroxide, calcium phosphate, or calcium sulfide. The complexing agent may include a nitrogen-containing group, a sulfur-containing group, a phosphorus-containing group, an acid, or a carbonyl group. For example, the complexing agent may include EDTA, cysteine, xanthates, or trimercaptotriazine. The complexing agent may include an ion exchange resin, beads, or membrane. The sorbent may include zeolites, metal oxides, zero valent iron, carbon, tannin-rich materials, modified natural fibers, and modified synthetic fibers. The sorbent may include an apatite, a clay, or an oxide. The stabilization agent may include a cementious material. The hydrophilic material may be part of a base chain of a polymeric adhesive or interlayer material.

A photovoltaic module can include a transparent conductive oxide layer adjacent to a substrate and layers of semiconductor material. The layers of semiconductor material can include a bi-layer, which may include an n-type semiconductor window layer, and a p-type semiconductor absorber layer. The n-type window layer and the p-type absorber layer may be positioned in contact with one another to create an electric field. Photons can free electron-hole pairs upon making contact with the n-type window layer, sending electrons to the n side and holes to the p side. Electrons can flow back to the p side via an external current path. The resulting electron flow provides current, which combined with the resulting voltage from the electric field, creates power. The result is the conversion of photon energy into electric power. To preserve and enhance device performance, numerous layers can be positioned above the substrate in addition to the semiconductor window and absorber layers.

The cadmium telluride thin film layer (and other cadmium-containing layers) can be positioned proximate to materials designed to seal and hold the module together for many years and under a variety of conditions. These remediation agents can help retain heavy metals present within the module by forming low solubility compounds that immobilize, chelate, adsorb, and/or fixate the cadmium and/or other heavy metals within the structure of the module to assist with handling and disposal. A hydrophilic barrier can be positioned adjacent to the remediation agent to prevent direct contact between the remediation agent and a constituent material (i.e., a heavy metal). For example, a photovoltaic module may include a remediation agent partially or completely encapsulated within a hydrophilic barrier, where the hydrophilic barrier is positioned proximate to a heavy metal. Upon contacting water, the hydrophilic barrier may swell or dissolve, releasing the remediation agent to interact with the heavy metal (i.e., to immobilize, chelate, adsorb, and or fixate the heavy metal within the module). The hydrophilic barrier may include a polyethylene and may contain a polymer or a resin. The hydrophilic barrier may include various molecular weight polyethylene oxide/polyethylene glycol polymers, and mixtures thereof. For example, the hydrophilic barrier may include polyethylene oxide/polyethylene glycol, methoxypolyethylene oxide, dimethyl ethers of polyethylene oxide, and any mixtures or combinations thereof, where the molecular weight is between about 200 and about 10,000,000. The molecules may be linear or branched and may contain additional cross-linking agents. The hydrophilic barrier may include ultra high molecular weight polyethylene, ultra low molecular weight polyethylene, high molecular weight polyethylene, high density polyethylene, medium density polyethylene, low density polyethylene, linear low density polyethylene, very low density polyethylene, or any mixtures or combinations thereof.

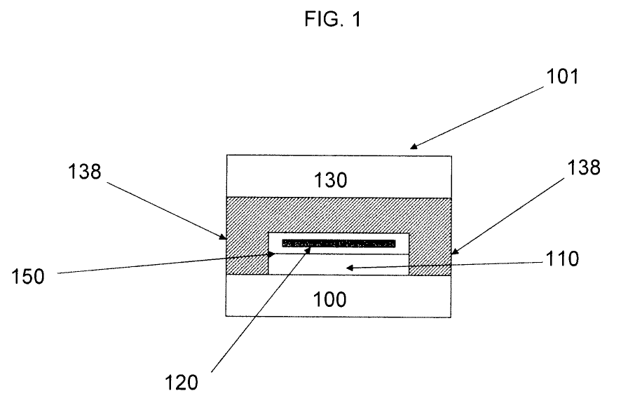

Referring to FIG. 1, a self-remediating photovoltaic module 101 can include a front support 100 and a back support 130. Front support 100 and back support 130 can include any suitable material, including glass, for example, soda-lime glass. One or more layers 110 can be deposited adjacent to front support 100, which can serve as a first substrate, on top of which various layers may be added. Layer(s) 110 can include one or more device layers. For example, layer(s) 110 can include a cadmium telluride absorber layer on a cadmium sulfide window layer. Layer(s) 110 can include additional metal layers adjacent to the cadmium telluride absorber layer. A remediation agent, such as a heavy metal-immobilizing agent 120, can be deposited adjacent to layer(s) 110. Heavy metal-immobilizing agent 120 can be separated from layer(s) 110 by a hydrophilic material 150. Hydrophilic material 150 may include a polyethylene and may contain a polymer or a resin. For example, hydrophilic material 150 may include polyethylene oxide/polyethylene glycol, methoxypolyethylene oxide, dimethyl ethers of polyethylene oxide, and any mixtures or combinations thereof, where the molecular weight is between about 200 and about 10,000,000. The molecules may be linear or branched and may contain additional cross-linking agents. Hydrophilic material 150 can be deposited in any suitable position within the photovoltaic module, including, for example, as a layer within the photovoltaic module, within an interlayer deposited proximate to the stack layers, or within an encapsulation frame surrounding the module. Hydrophilic material 150 may also be deposited within the scribes of the module. Hydrophilic material 150 may provide a barrier between heavy metal-immobilizing agent 120 and layer(s) 110. For example, hydrophilic material 150 may partially or completely encapsulate heavy metal-immobilizing agent 120 as depicted in FIG. 1. Upon contact with water, hydrophilic material 150 may swell or dissolve, permitting or facilitating chemical interaction between heavy metal-immobilizing agent 120 and layer(s) 110.

Heavy metal-immobilizing agent 120 can include any suitable remediation material, including, for example, a precipitating agent, a complexing agent, a sorbent, or a stabilizing agent. The precipitating agent can include various suitable materials, including, for example, FeS, Na₂S, CaS, Ca(OH)₂, NaOH, CaHPO₄, Ca(H₂PO₄)₂, CaCO₃, CaSiO₃, or combinations thereof. The complexing agent can include various suitable materials. For example, the complexing agent can include any suitable imino group, thiol group, disulfide, carbamate, or acid group. Examples may include, but are not limited to, EDTA, cysteine, xanthates, trimercaptotriazines, di-n-propyldithiophosphates, or any combinations or mixtures thereof. Possible sorbents include, but are not limited to, zeolites (synthetic or natural, or modified or non-modified), lignin, chitosan, dead biomass, fly ash, clay, apatite, metal oxides (hydrous or non-hydrous), zero valent iron, carbon, tannin-rich materials, or combinations or mixtures thereof. The stabilization material can include a cementious material such as pozzolan. Photovoltaic module 101 can include one or more interlayers 138, positioned adjacent to layer(s) 110 and front and back supports 100 and 130. Hydrophilic material 150 can be deposited within the laser scribes of any of layer(s) 110, or on either side of the front and back supports, with heavy metal-immobilizing agent 120 deposited thereon.

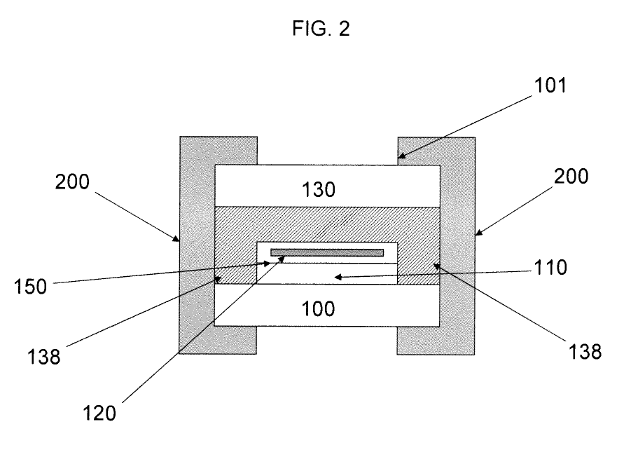

Heavy metal-immobilizing agent 120 may be incorporated into hydrophilic material 150 using any suitable technique and in any suitable spatial orientation. For example, heavy metal-immobilizing agent 120 may be dispersed in a uniform manner or in a concentration gradient within hydrophilic material 150. Heavy metal-immobilizing agent 120 may be sandwiched between layers of hydrophilic material 150, or partially or completely encapsulated within hydrophilic material 150. Referring to FIG. 2, an encapsulation frame 200 can be placed around photovoltaic module 101 to hold the module layers together.

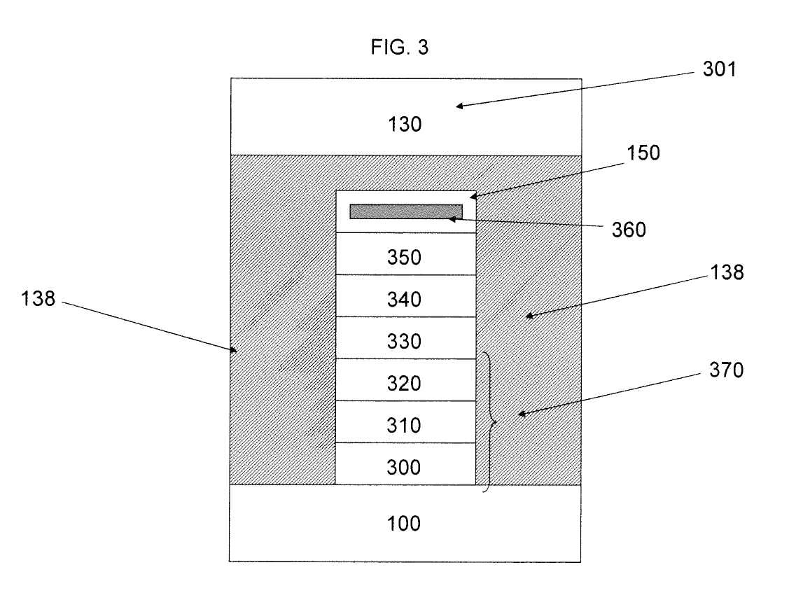

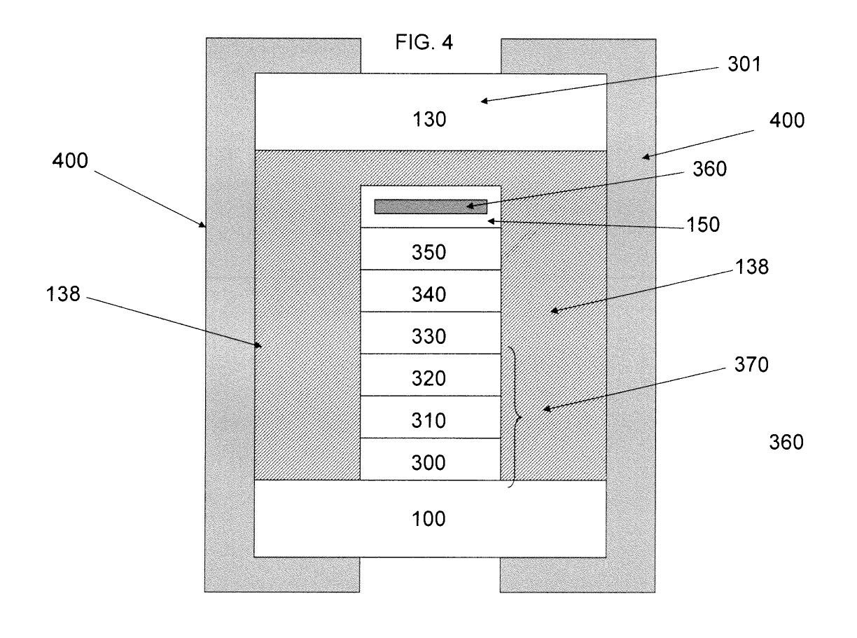

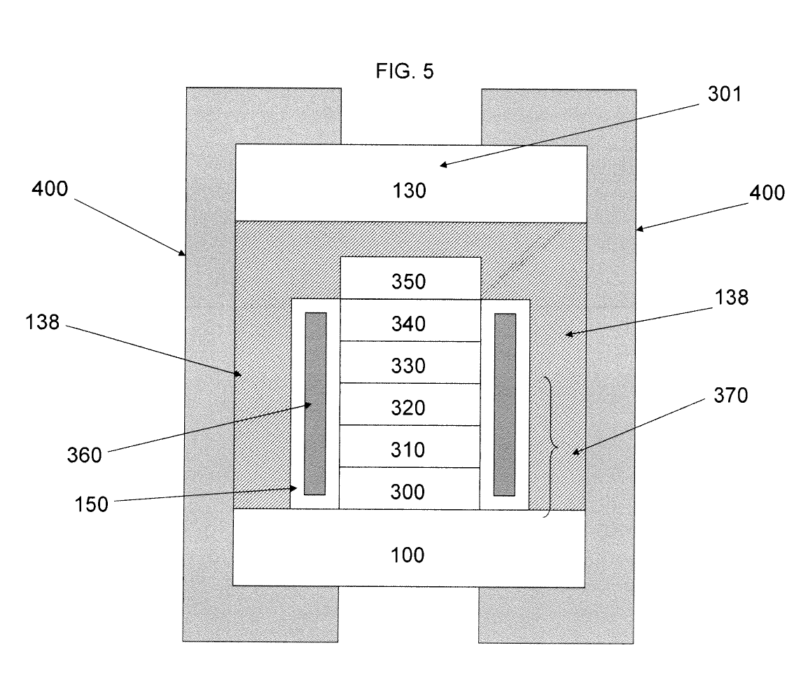

Referring to FIG. 3, a photovoltaic module 301 can include a hydrophilic material 150 between a heavy metal-immobilizing agent 360 and one or more layers of the module. Hydrophilic material 150 can provide a separation barrier between heavy metal-immobilizing agent 360 and any other layer. For example, hydrophilic material 150 can partially or completely encapsulate heavy metal-immobilizing agent 360. Photovoltaic module 301 may also include a transparent conductive oxide stack 370, which may include a transparent conductive oxide layer 310 deposited on a barrier layer 300, and a buffer layer 320 deposited on transparent conductive oxide layer 310. Barrier layer 300, transparent conductive oxide layer 310, and buffer layer 320 can be deposited using any suitable deposition technique, including, for example, sputtering. Transparent conductive oxide stack 370 can be annealed prior to the deposition of subsequent layers. Cadmium sulfide layer 330 can be deposited adjacent to transparent conductive oxide stack 370 after annealing. Cadmium telluride layer 340 can be deposited onto cadmium sulfide layer 330. Cadmium sulfide layer 330 and cadmium telluride layer 340 can be deposited using any suitable deposition technique, including vapor transport deposition. One or more additional metal layers can be deposited adjacent to cadmium telluride layer 340. For example, a back contact metal 350 can be deposited adjacent to cadmium telluride layer 340. Back contact metal 350 can be deposited using any suitable deposition technique, including sputtering. Heavy metal-immobilizing agent 360 (proximate to and/or encapsulated by hydrophilic material 150) can be deposited adjacent to cadmium telluride layer 340 or adjacent to back contact metal 350. Heavy metal-immobilizing agent 360 can be suitable for immobilizing heavy metals or any other metals, such as mercury or lead. Heavy metal-immobilizing agent 360 (proximate to and/or encapsulated by hydrophilic material 150) can also be deposited on a barrier layer. The barrier layer can be placed adjacent to a heavy metal-containing layer or adjacent to one or more additional metal layers. The barrier layer can also be patterned, and the heavy metal-immobilizing agent (proximate to and/or encapsulated by hydrophilic material 150) can be selectively placed on the barrier layer. The barrier layer can include a polymer or a ceramic and can be deposited by any suitable means. Heavy metal-immobilizing agent 360 (proximate to and/or encapsulated by hydrophilic material 150) can also be deposited within cadmium telluride layer 340 within the laser scribes. Referring to FIG. 5, a heavy metal-immobilizing agent 360, encapsulated by hydrophilic material 150 can be deposited as part of an interlayer 138 between front support 100 and back support 130, adjacent to one or more intermediate layers (i.e., layer(s) 110 from FIG. 1). Interlayer 138 can include any suitable interlayer material, including for example, a heavy metal-immobilizing agent. Hydrophilic material 150 can be part of interlayer 138. Referring to FIG. 4, heavy metal-immobilizing agent 360 can be deposited directly onto cadmium telluride layer 340 or deposited directly onto back contact metal 350. Heavy metal-immobilizing agent 360 can be positioned proximate to or secured within hydrophilic material 150 and deposited directly onto cadmium telluride layer 340 or back contact metal 350.

Hydrophilic barrier 150 can be deposited using any suitable technique, including, for example, spin coating, as well as placement of free-standing or extruded films. For example, hydrophilic material 150 can be patterned onto the surface of cadmium telluride layer 340, back contact metal 350, interlayer 138, or back support 130. Hydrophilic material 150 can be sprayed onto the cadmium telluride layer 340, back contact metal 350, interlayer 138, or back support prior to interlayer placement or lamination. The spray solution can be solvent-based, or it can be water-based; and the viscosity of the solution can be adjusted to achieve a suitable level of viscosity for spray and/or screen-printed application. Hydrophilic material 150 can be screen-printed onto the cadmium telluride layer 340, back contact metal 350, interlayer 138, or back support 130 prior to interlayer placement or lamination. Hydrophilic material 150 can undergo a drying process. Photovoltaic module 301 can be encapsulated in frame 400 from FIGS. 4 and 5. Heavy metal-immobilizing agent 360 can be deposited within or proximate to hydrophilic material 150, and then deposited within photovoltaic module 301. Frame 400 can include heavy metal-immobilizing agent 360 within or proximate to hydrophilic material 150.

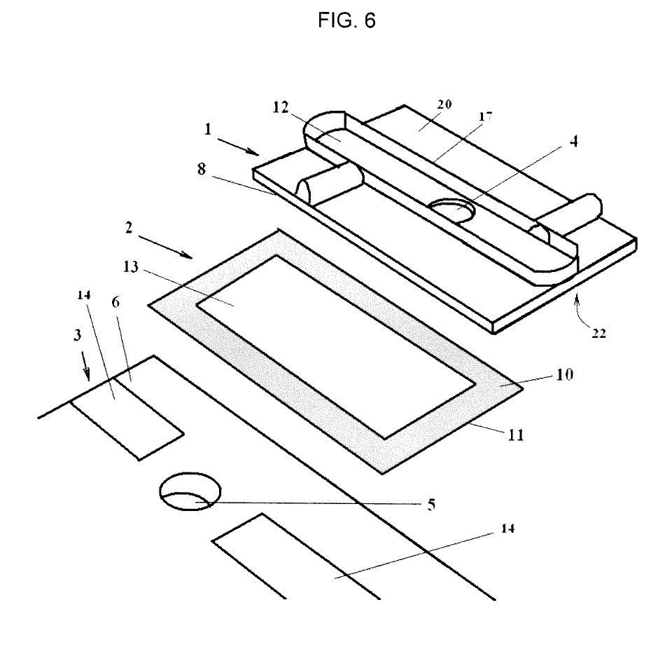

A heavy metal-immobilizing agent can also be suitable for immobilizing other heavy metals present within the module, including cord plate solder. For example, referring to FIG. 6, cover plate or back support 130 has first surface 6. Back support 130 can include a connector 5. Connector 5 can be any suitable connector, such as a hole formed in back support 130. Connector 5 can be an impression formed in first surface 6 of back support 130. Connector 5 can be connected to the photovoltaic device of the photovoltaic module. The heavy metal-immobilizing agent (within or proximate to hydrophilic material 150) can be included in a component of the cord plate assembly, such as a flowable sealant. Suitable cord plates are described, for example, in U.S. Application No. 61/159,504 filed Mar. 12, 2009, which is incorporated by reference in its entirety.

Photovoltaic devices/modules fabricated using the methods discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A method for manufacturing a photovoltaic module, the method comprising:
forming a photovoltaic device comprising a constituent material;
forming a hydrophilic material adjacent to the constituent material, wherein the hydrophilic material comprises polyethylene; and
depositing a remediation agent adjacent to the hydrophilic material, such that the remediation agent is proximate to, but not contacting the constituent material.

2. The method of claim 1, wherein the hydrophilic material comprises a polyethylene oxide/polyethylene glycol, a resin, or a polymer, or is part of a base chain of a polymeric adhesive or interlayer material.

3. The method of claim 2, wherein the polymer comprises an oxide, a glycol, a methoxypolyethylene oxide, a dimethyl ether of polyethylene oxide, a mixture including any combination of oxide, glycol, methoxypolyethylene oxide, and a dimethyl ether of polyethylene oxide.

4. The method of claim 1, wherein the constituent material comprises:
a heavy metal;
cadmium;
a semiconductor absorber layer on a semiconductor window layer; or
a cadmium telluride layer on a cadmium sulfide layer.

5. The method of claim 1, wherein the remediation agent comprises a precipitating agent, a complexing agent, a sorbent, or a stabilization agent.

6. The method of claim 5, wherein:
the precipitating agent comprises:
a material selected from the group consisting of sulfide, hydroxide, carbonate, phosphate, and silicate; or
a calcium carbonate, calcium hydroxide, calcium phosphate, or calcium sulfide;
the complexing agent comprises:
a nitrogen-containing group, a sulfur-containing group, a phosphorus-containing group, an acid, or a carbonyl group;
EDTA, cysteine, xanthates, or trimercaptotriazine; or
an ion exchange resin, beads, or membrane;
the sorbent comprises:
a material selected from the group consisting of zeolites, metal oxides, zero valent iron, carbon, tannin-rich materials, modified natural fibers, and modified synthetic fibers; or
an apatite, a clay, or an oxide; or
the stabilization agent comprises a cementious material.

7. The method of claim 1, wherein the step of forming a hydrophilic material comprises:
contacting the hydrophilic material to the constituent material;
encapsulating the remediation agent within the hydrophilic material;
depositing the hydrophilic material in the laser scribes of a heavy metal;
spin coating;
placing a free-standing film;
placing an extruded film; or
dispersing the hydrophilic material throughout an interlayer near a polymer-metal interface.

8. The method of claim 1, further comprising laminating one or more layers, wherein the photovoltaic module comprises the one or more layers.

9. A photovoltaic module comprising:
a photovoltaic device comprising a constituent material;
a remediation agent proximate to the constituent material, wherein the remediation agent is capable of remediating the constituent material; and
a hydrophilic material positioned between the constituent material and the remediation agent, wherein the hydrophilic material comprises polyethylene.

10. The photovoltaic module of claim 9, wherein the hydrophilic material comprises a resin, a polymer, an oxide, a glycol, a methoxypolyethylene oxide, a dimethyl ether of polyethylene oxide, or a mixture including any combination of oxide, glycol, methoxypolyethylene oxide, and a dimethyl ether of polyethylene oxide.

11. The photovoltaic module of claim 9, wherein the constituent material comprises:
a heavy metal;
cadmium;
a semiconductor absorber layer on a semiconductor window layer; or
a cadmium telluride layer on a cadmium sulfide layer.

12. The photovoltaic module of claim 9, wherein the remediation agent comprises a precipitating agent, a complexing agent, a sorbent, or a stabilization agent.

13. The photovoltaic module of claim 12, wherein:
the precipitating agent comprises:
a material selected from the group consisting of sulfide, hydroxide, carbonate, phosphate, and silicate; or
a calcium carbonate, calcium hydroxide, calcium phosphate, or calcium sulfide;
the complexing agent comprises:
a nitrogen-containing group, a sulfur-containing group, a phosphorus-containing group, an acid, or a carbonyl group;
EDTA, cysteine, xanthates, or trimercaptotriazine; or
an ion exchange resin, beads, or membrane.
the sorbent comprises:
a material selected from the group consisting of zeolites, metal oxides, zero valent iron, carbon, tannin-rich materials, modified natural fibers, and modified synthetic fibers; or
a zeolite, an apatite, a clay, or an oxide; or
the stabilization agent comprises a cementious material.

14. The photovoltaic module of claim 9, wherein the hydrophilic material is part of a base chain of a polymeric adhesive or interlayer material.
